(19) United States
(12) Patent Application Publication
(10) Pub. No.: US 2026/0372018 A1
(43) Pub. Date: Nov. 19, 2026

(54) METHOD AND SYSTEM FOR ENDPOINT DETECTION USING HYPERSPECTRAL IMAGING

(71) Applicant: Tokyo Electron Limited, Tokyo (JP)

(72) Inventors: Nicholas Smieszek, Albany, NY (US); Qi Wang, Albany, NY (US); Shuyan Zhang, Fremont, CA (US); Hwang-Jye Yang, Fremont, CA (US); Sergey Voronin, Albany, NY (US); Francisco Machuca, Fremont, CA (US)

(21) Appl. No.: 19/212,332

(22) Filed: May 19, 2025

(51) Int. Cl. H10P 74/00; G01N 21/73; H10P 50/28

(52) U.S. Cl. CPC H10P 74/238; G01N 21/73; H10P 50/283; G01N 2201/08

(57) ABSTRACT

A method is provided for processing a substrate with repeating stacks of alternating material layers. The method includes loading a substrate in a process chamber, where the substrate includes repeating stacks of alternating first material layers and second material layers. The method further includes etching the repeating stacks by exposing the substrate to a plasma. During the etching process, hyperspectral images of the plasma are acquired to monitor the progression through the alternating layers. An endpoint of the etching is determined based on the acquired hyperspectral images, specifically when oscillating intensity patterns in the images cease, indicating complete etching of the repeating stacks. The etching process is stopped after determining the endpoint.

### TECHNICAL FIELD

The present invention relates generally to a system and method of semiconductor manufacturing characterization, and, in particular embodiments, to a system and method for endpoint detection using hyperspectral imaging.

### BACKGROUND

Generally, a semiconductor device, such as an integrated circuit (IC) is fabricated by sequentially depositing and patterning layers of dielectric, conductive, and semiconductor materials over a substrate to form a network of electronic components and interconnect elements (e.g., transistors, resistors, capacitors, metal lines, contacts, and vias) integrated in a monolithic structure. Process flows used to form the constituent structures of semiconductor devices often involve depositing and removing a variety of materials while a pattern of several materials may be exposed in a surface of the working substrate.

Advanced process control that involves process and system characterization and fault detection in semiconductor manufacturing is essential for reproducible production of complex structures. Especially in high-volume manufacturing, plasma system monitoring is of paramount importance for process consistency. As the minimum dimension of features in a patterned layer has shrunk periodically and new materials have been introduced in ICs, the need for improved plasma system monitoring to assure process compliance and cost reduction has increased.

### SUMMARY

In accordance with one aspect of the present invention, a method is provided for processing a substrate. The method includes loading a substrate in a process chamber, the substrate comprising repeating stacks of alternating first material layers and second material layers. The method further includes etching the repeating stacks by exposing the substrate to a plasma, determining an endpoint of the etching based on hyperspectral images of the plasma acquired during the etching, and stopping the etching after determining the endpoint.

In accordance with another aspect of the present invention, a method is provided for endpoint detection during etching of multilayer structures. The method includes providing a substrate with repeating stacks of alternating first material layers and second material layers in a process chamber and initiating an etching process to etch the repeating stacks. The method further includes coupling a hyperspectral imaging system to the process chamber to monitor the etching process, acquiring hyperspectral data from the etching process, and processing the hyperspectral data to enhance signal-to-noise ratio. The method also includes analyzing the hyperspectral data to identify oscillating intensity patterns at wavelengths associated with etching byproducts of the first material layers and the second material layers, monitoring changes in the oscillating intensity patterns during the etching process, and determining that an endpoint of the etching process is reached when the oscillating intensity patterns cease.

In accordance with yet another aspect of the present invention, a method is provided for processing a substrate. The method includes providing a substrate in a process chamber, the substrate comprising repeating stacks of alternating first material layers and second material layers, and etching the repeating stacks in the process chamber. The method further includes removing exhaust gas from the process chamber to an exhaust chamber coupled to the process chamber and generating an exhaust plasma from the exhaust gas in the exhaust chamber. The method also includes coupling an optical emission spectroscopy (OES) detector to the exhaust chamber, continuously acquiring OES data of the exhaust plasma through the OES detector, and monitoring specific wavelengths in the OES data corresponding to the first material layers and the second material layers. The method further includes identifying oscillating intensity patterns in the specific wavelengths as the alternating first material layers and second material layers are etched, and determining an endpoint of the etching when the oscillating intensity patterns cease.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate cross-sectional views of a substrate with repeating stacks of alternating material layers at different stages of etching, in accordance with an embodiment;

FIGS. 2A and 2B illustrate schematic views of process chambers with a hyperspectral imaging (HSI) system and an optical emission spectroscopy (OES) detector for endpoint detection, respectively, in accordance with an embodiment;

FIGS. 3A-3C illustrate comparative data showing endpoint detection capabilities of different monitoring systems, in accordance with an embodiment;

FIGS. 4A-4B illustrate oscillating intensity patterns observed during etching of repeating stacks and their cessation at endpoint, in accordance with an embodiment;

FIG. 5 illustrates a process flow diagram for an HSI-based endpoint detection method for etching repeating stacks, in accordance with an embodiment; and

FIG. 6 illustrates a process flow diagram for an OES-based endpoint detection method using an exhaust plasma chamber, in accordance with an embodiment.

### DETAILED DESCRIPTION OF ILLUSTRATIVE EMBODIMENTS

Oxide-Nitride-Oxide (ONO) stacks are widely used in semiconductor manufacturing for applications such as memory devices, where multiple alternating layers of oxide and nitride materials are precisely stacked and etched. It is challenging to accurately detect the endpoint during etching of the ONO stacks, particularly due to the high aspect ratio and small open areas of etching features. These characteristics result in poor signal-to-noise ratio (SNR) for conventional endpoint detection methods, making it difficult to determine when etching has reached the desired depth. Consequently, the current standard practice relies on time-based etching, which lacks precision and may lead to under-etching or over-etching.

In various embodiments, a hyperspectral imaging (HSI) system coupled to a process chamber may accurately detect the endpoint during etching of the ONO stacks. The HSI system may achieve higher signal-to-noise ratio compared to conventional optical emission spectroscopy (OES) systems, enabling the detection of subtle spectral changes. In one or more embodiments, the HSI approach enables spatial and frame averaging improvements to signal-to-noise ratio, allowing for more effective filtering of noise and extraction of meaningful signals. Additionally, HSI allows for monitoring the spatial distribution of chamber intensity in real-time, providing comprehensive data about the etching process across the process chamber.

In another embodiment, an OES detector coupled to an exhaust chamber may be used for endpoint detection. This configuration takes advantage of the exhaust plasma generated from the exhaust gas, which can provide higher signal-to-noise ratio compared to directly monitoring the process chamber. The exhaust-based approach strengthens the emission signals, making it easier to detect changes in the optical emission spectra corresponding to different material layers being etched.

In various embodiments, the endpoint detection techniques described herein monitor oscillating intensity patterns that correspond to the alternating etching of different material layers in the stack. As each layer is etched, characteristic wavelengths associated with etching byproducts (such as 440 nm for oxide etching and 387 nm for nitride etching) may exhibit oscillating intensity patterns. This approach may provide higher accuracy than merely observing a single intensity drop, which is particularly important for alternating material layers where multiple transitions occur during the etching process. The endpoint may be determined when these oscillation intensity patterns cease, indicating that the etching may reach the desired depth through the entire stack.

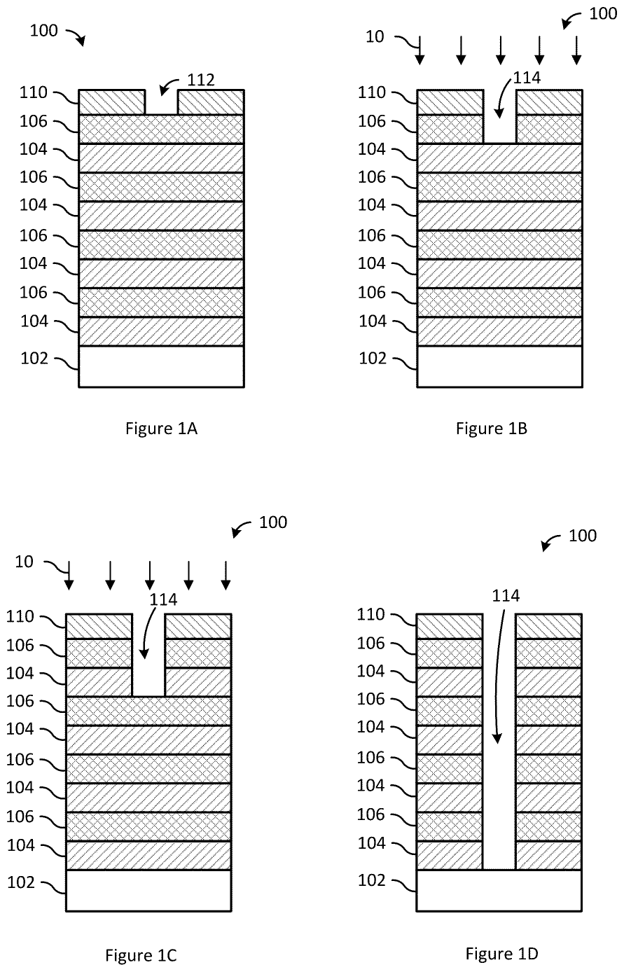

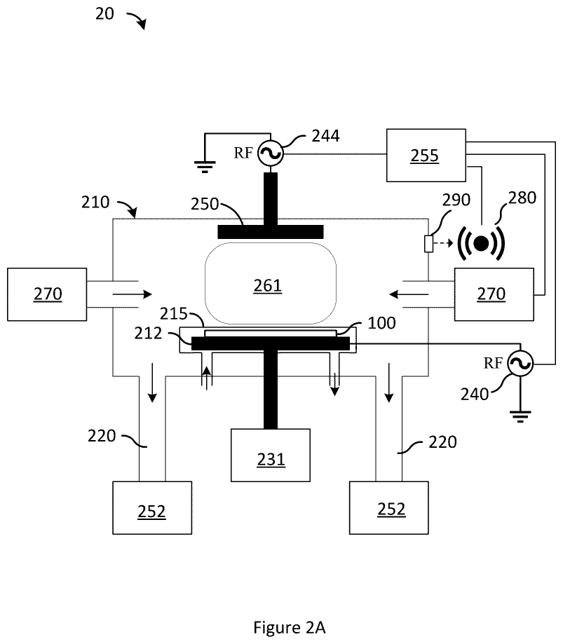

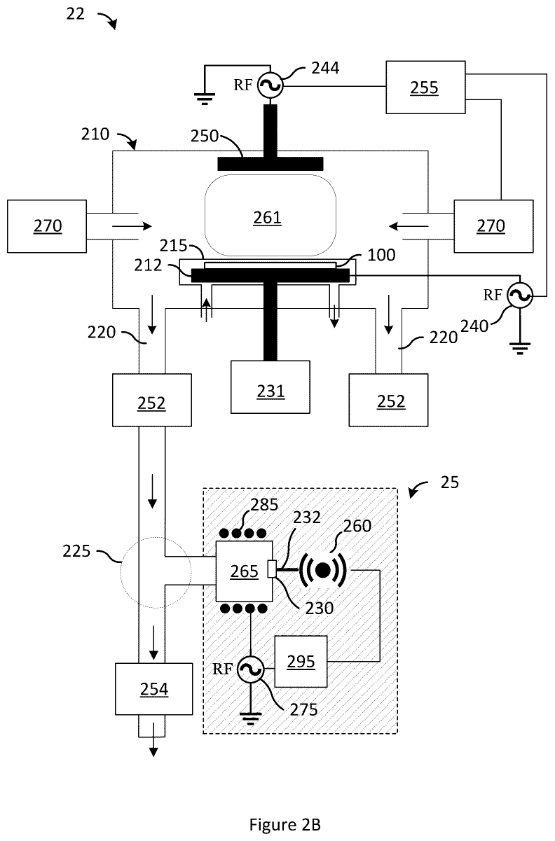

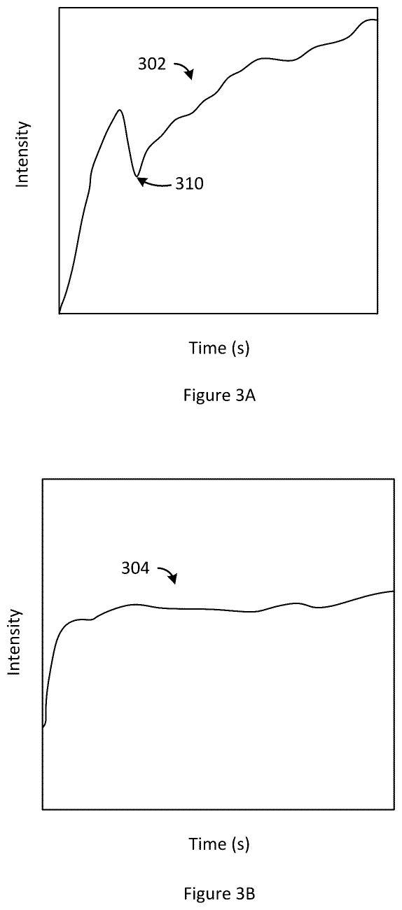

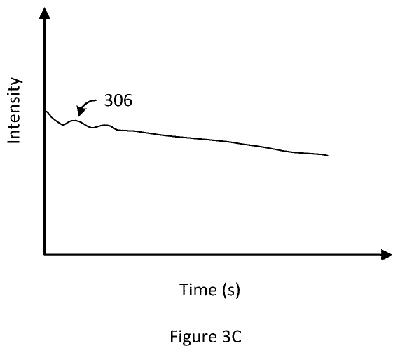

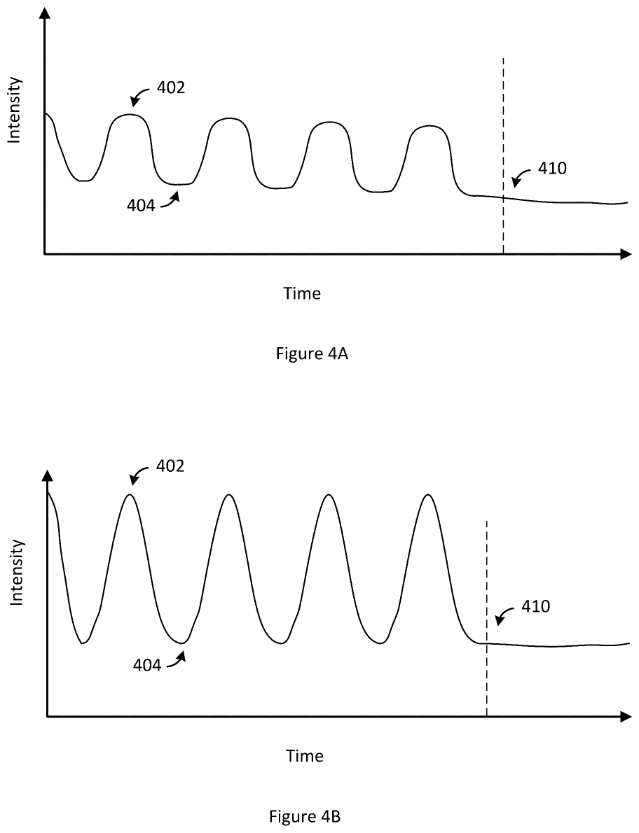

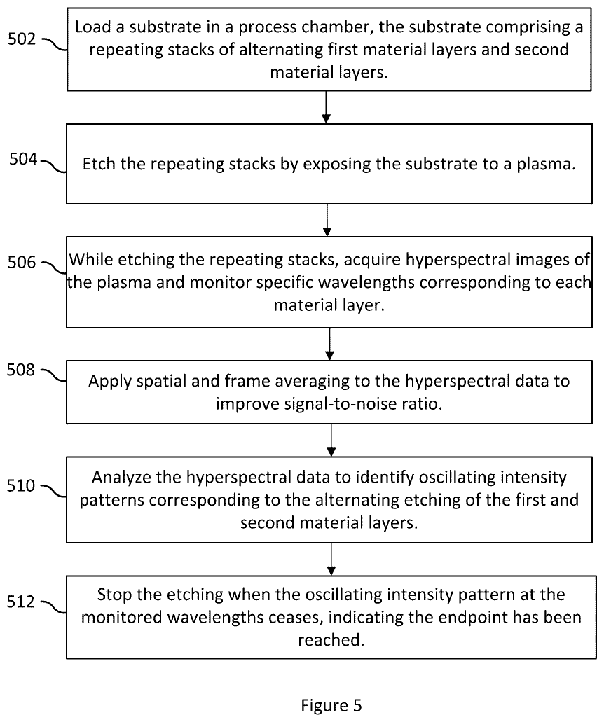

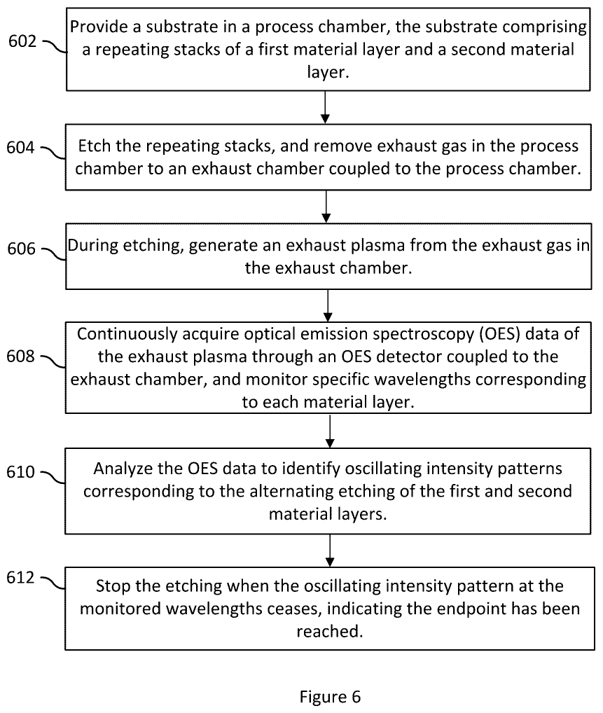

Embodiments of the disclosure are described in the context of the accompanying drawings. An embodiment of a substrate with repeating stacks of alternating material layers at different stages of etching is illustrated in FIGS. 1A-1D. A first embodiment with a hyperspectral imaging (HSI) system coupled to a process chamber is shown in FIG. 2A. A second embodiment with an optical emission spectroscopy (OES) detector coupled to an exhaust plasma chamber is illustrated in FIG. 2B. Experimental data comparing endpoint detection capabilities of different systems are presented in FIGS. 3A-3C. Exemplary oscillating intensity patterns observed during etching and their cessation at endpoint are shown in FIGS. 4A-4B. A process flow diagram for the HSI-based endpoint detection method is presented in FIG. 5. A process flow diagram for the OES-based endpoint detection method using an exhaust plasma chamber is illustrated in FIG. 6.

FIGS. 1A-1D illustrates cross-sectional views of a substrate with repeating stacks of alternating material layers for etching, in accordance with an embodiment.

In FIG. 1A, a substrate 100 comprising repeating stacks of alternating material layers is provided in a process chamber. In various embodiments, the substrate 100 may comprise a substrate layer 102, repeating stackings of alternating first material layers 104 and second material layers 106, and a patterned mask layer 110 formed over the repeating stacks. In one or more embodiments, the substrate layer 102 may comprise a bulk substrate such as a blank silicon wafer, a silicon-on-insulator (SOI) wafer, or any of various other semiconductor substrates. The substrate layer 102 may also be coated or layered with any number of additional materials, including compound semiconductors, metal or metal oxides, or metal nitrides. The substrate layer 102 may include any material portion or structure of a device, particularly a semiconductor or other electronics device.

In various embodiments, the repeating stacks comprising alternating first material layers 104 and second material layers 106 may be disposed over the substrate layer 102. In various embodiments, the first material layers 104 may comprise oxide layers such as silicon oxide, aluminum oxide, hafnium oxide, zirconium oxide, tantalum oxide, titanium oxide, or combinations thereof. In various embodiments, the second material layers 106 may comprise nitride layers such as silicon nitride, aluminum nitride, titanium nitride, boron nitride, silicon oxynitride, or silicon carbonitride. In one or more embodiments, each of the first and second materials layers 104 and 106 may comprise a thickness between 10 nm to 30 nm. In an embodiment, the first materials layer 104 may be approximately 30 nm and the second materials layer 106 may be approximately 25 nm. In various embodiments, the first and second materials layers 104 and 106 may be deposited using various deposition techniques including chemical vapor deposition (CVD), plasma-enhanced chemical vapor deposition (PECVD), atomic layer deposition (ALD), physical vapor deposition (PVD), sputtering, or other suitable deposition methods.

In some embodiments, the repeating stacks may comprise 100 to 200 pairs of alternating first and second material layers, and in a specific embodiment, may include approximately 133 pairs of alternating layers. In some embodiments, a total thickness of the repeating stacks may range from 4 to 8 μm. In one embodiment, the total thickness may be approximately 6 μm. In some embodiments, the repeating stacks may be Oxide-Nitride-Oxide (ONO) stacks, which may be used in semiconductor memory devices and non-volatile memory applications.

In various embodiments, the patterned mask layer 110 may be deposited over the repeating stacks. In various embodiments, the patterned mask layer 110 may comprise silicon oxide, silicon nitride, silicon carbonitride (SiCN), or silicon oxycarbide (SiOC). In alternate embodiments, the patterned mask layer 110 may comprise titanium nitride. In one or more embodiments, the patterned mask layer 110 may comprise other suitable organic materials such as spin-on carbon hard mask (SOH) materials. In alternative embodiments, the patterned mask layer 110 may be a stacked hard mask comprising, for example, two or more layers using two different materials. In some of such embodiments, the first hard mask of the patterned mask layer 110 may comprise a metal-based layer such as titanium nitride, titanium, tantalum nitride, tantalum, tungsten-based compounds, ruthenium-based compounds, or aluminum-based compounds, and the second hard mask material of the patterned mask layer 110 may comprise a dielectric layer such as silicon oxide, silicon nitride, SiCN, SiOC, silicon oxynitride, or silicon carbide. In various embodiments, the patterned mask layer 110 may comprise an opening 112 that define the areas where etching will occur.

FIG. 1B illustrates a cross-sectional view of the substrate 100 during an etching process, in accordance with an embodiment. In various embodiments, the etching process may utilize a continuous plasma process with an etch chemistry capable of etching both the first material layers 104 and second material layers 106, eliminating the need for chemistry changes during etching. Alternatively, in some embodiments, the etching process may be a cyclic plasma process with each cycle of the cyclic plasma process using different chemistries optimized for etching each type of material layer in the alternating stacks. In various embodiments, the etching process may begin by flowing an etch gas into the process chamber and generating a plasma 10 from the etch gas. In various embodiments, the plasma 10 may be generated by applying RF power to a source power coupled to the process chamber. In various embodiments, the RF power applied to the source may range from about 500 W to about 5500 W at frequencies between 1 MHz and 50 MHz, for example, 40 MHz. In some embodiments, the plasma generation may also include applying RF or DC power to a bias power coupled to a substrate holder holding the substrate 100. The bias power may range from about 0 W to about 9500 W and help control the ion energy of the plasma species directed toward the substrate surface.

In various embodiments, the etch gas may comprise a fluorocarbon gas such as CF₄, C₂F₆, C₃F₈, C₄F₈, CHF₃, or the like. In some embodiments, the etch gas may further comprise oxygen, nitrogen, argon, helium, hydrogen, krypton, or carbon monoxide which is mixed with the fluorocarbon gas. In some embodiments, the etch gas may also comprise NF₃, SF₆, or other halogen-containing gases to enhance the etching process.

In various embodiments, the repeating stacks may be etched using the patterned mask layer 110 as an etch mask by exposing the substrate 100 to the plasma 10. The plasma 10 may interact with the exposed portions of the repeating stacks through the opening 112 in the patterned mask layer 110, selectively removing material to form an etched feature 114.

In various embodiments, the etching process may form the etched feature 114 in the repeating stacks with an aspect ratio over 10:1, wherein the depth of the etched feature 114 may be more than ten times greater than the width. The high aspect ratio may make endpoint detection particularly challenging using conventional methods. In some embodiments, the etched feature 114 may have an open area ratio of less than 10% of a total surface area of the substrate 100, which further complicates endpoint detection due to the relatively small amount of material being removed compared to the total substrate surface area. As will be described later in detail with reference to FIGS. 2A-2B, the process chamber may be coupled to a hyperspectral imaging (HSI) camera or an optical emission spectroscopy (OES) detector (coupled to an exhaust plasma chamber) for accurate endpoint detection.

FIG. 1C illustrates a cross-sectional view of the substrate 100 during continuation of the etching process described in FIG. 1B. As the etching process continues, the etched feature 114 may deepen further into the repeating stacks of alternating first material layers 104 and second material layers 106. The plasma 10 may continue to interact with the exposed portions of the repeating stacks through the opening 112 in the patterned mask layer 110, progressively removing more material layers. In various embodiments, the HSI camera or the OES detector illustrated in FIGS. 2A-2B may acquire optical emissions from the plasma during the etching process to precisely monitor the progression through the alternating material layers.

FIG. 1D illustrates the substrate 100 at the completion of the etching process, in accordance with an embodiment. In FIG. 1D, the etching process has progressed through all the repeating stacks of alternating first material layers 104 and second material layers 106, with the etched feature 114 extending all the way down to expose a top surface of the substrate layer 102. This represents the desired endpoint of the etching process for applications requiring complete removal of the repeating stacks in the patterned areas. In various embodiments, the HSI camera or the OES detector illustrated in FIGS. 2A-2B may acquire optical emissions from the plasma during the etching process to precisely monitor the progression through the alternating material layers and detect the endpoint. In various embodiments, the completed etched feature 114 shown in FIG. 1D may have an aspect ratio over 10:1 and an open area ratio of less than 10% of the total surface area of the substrate. In one or more embodiments, the patterned mask layer 110 may be removed in subsequent processing steps.

FIG. 2A illustrates a schematic view of a processing system 20 integrating a hyperspectral imaging (HSI) camera with the process chamber for endpoint detection, in accordance with an embodiment. In various embodiments, the HSI camera may also be referred to as a hyperspectral imaging (HSI) system. The HSI camera may achieve higher signal-to-noise ratio compared to conventional OES detectors, enabling detection of subtle spectral changes in etched features with high aspect ratio and small open area. In various embodiments, processing of the substrate 100 illustrated in FIGS. 1A-1D may be performed using the processing system 20.

In various embodiments, the substrate 100 illustrated in FIGS. 1A-1D may be placed on a substrate holder 212 (e.g., a circular electrostatic chuck (ESC)) inside a process chamber 210 near the bottom. The substrate 100 may be optionally maintained at a desired temperature using a heater/cooler 215 that surrounds the substrate holder 212. The temperature of the substrate 100 may be maintained by a temperature controller 231 connected to the substrate holder 212 and the heater/cooler 215. In some embodiments, the ESC may be coated with a conductive material (e.g., a carbon-based or metal-nitride based coating) so that electrical connections may be made to the substrate holder 212.

Process gases such as the etch gas described with reference to FIG. 1B may be introduced into the process chamber 210 by a gas delivery system 270. The gas delivery system 270 may comprise multiple gas flow controllers to control the flow of multiple gases into the process chamber 210. Each of the gas flow controllers of the gas delivery system 270 may be assigned for each of fluorocarbons, noble gases, and/or balancing agents. In some embodiments, optional center/edge splitters may be used to independently adjust the gas flow rates at the center and edge of the substrate 100. The process gases or any exhaust gases may be evacuated from the process chamber 210 through exhaust lines 220 using vacuum pumps 252. In one or more embodiments, a chamber control unit 255 may be coupled to the gas delivery system 270 to control the frequency, duration, composition, flow rate of gases delivered into the process chamber 210.

As illustrated in FIG. 2A, the substrate holder 212 may be a bottom electrode of the process chamber 210. In the illustrative example in FIG. 2A, the substrate holder 212 may be coupled to a RF power source 240 which may serve as a bias power source. In some embodiments, a conductive circular plate inside the process chamber 210 near the top is the top electrode 250. In FIG. 2A, the top electrode 250 may be coupled to another RF power source 244 of the processing system 20. In various embodiments, all of power sources for plasma processing (e.g., RF power sources 240 and 244) may be coupled to the chamber control unit 255 to enable synchronized or non-synchronized operations of the power sources. Although not specifically illustrated, any RF power source (e.g., RF power sources 240 and 244) may comprise a power generator, an amplifier, a function generator, and a matching network. In various embodiments, a plasma 261 may be generated in the region between the substrate 100 and the top electrode 250 by applying power to the RF power source 244. In certain embodiment, the plasma 261 may represent the plasma 10 described with reference to FIG. 1B.

In various embodiments, an HSI camera 280 may be coupled to the chamber control unit 255 and the process chamber 210 through a transparent viewport 290. The transparent viewport 290 is configured to enable transmission of hyperspectral images within the process chamber 210 to an externally mounted camera, for example, the HSI camera 280. In various embodiments, the transparent viewport 290 may comprise optically transparent materials suitable for transmitting hyperspectral images, such as quartz, sapphire, glass, or other similar materials that provide sufficient optical transmission in the desired wavelength range. The transparent viewport 290 may be configured in various shapes, such as circular, rectangular, honeycomb, or other geometric configurations.

The HSI camera 280 may comprise various electrical and optical components required to perform detection, recording, and analysis of the hyperspectral images (or referred to as hyperspectral data) from the plasma 261. In various embodiments, the HSI camera 280 may comprise an interferometer, an optical system, a sensor, a memory, and processor(s). In various embodiments, the HSI camera 280 may comprise a controller. The HSI camera 280 may be configured to receive a command from the controller to perform a series of operations accordingly: filtering wavelengths of hyperspectral images with the interferometer, focusing and directing the filtered hyperspectral images through the optical system, detecting and converting hyperspectral images to digital data through the sensor, recording and storing the digital data on the memory, and processing the digital data with the processor(s) through executable program stored in the memory.

In one or more embodiments, the interferometer may be a tunable Fabry-Pérot interferometer or an acousto-optic tunable filter (AOTF) or a liquid crystal tunable filter or a Michelson interferometer for selective wavelength filtering. In some embodiments, the interferometer may comprise a frequency generator, a piezoelectric actuator, and integrated suite of electronic components including a high-resolution analog-to-digital converter (ADC), digital signal processor (DSP), and communication interfaces for robust signal generation, acquisition, processing, and data transmission. The frequency generator may produce the electrical signals necessary to modulate the interferometer's gap, while the piezoelectric actuator controls the physical movement of the reflective surfaces. In some embodiments, the interferometer may operate in a free-run scanning mode, dynamically varying the distances between reflective surfaces to capture a wider range of wavelengths across hyperspectral images. This mode allows for comprehensive hyperspectral image collection and analysis, providing detailed information into the plasma at a wide wavelength range. Alternatively, the interferometer may operate in a fixed gap non-scanning mode, maintaining a constant distance between reflective surfaces to target specific wavelengths of hyperspectral images with high accuracy. This configuration ensures stable and focused transmitted intensity at chosen wavelengths, ideal for precise monitoring tasks. The dual-mode functionality of the interferometer offers the HSI camera 280 a versatile solution for both broad-spectrum and targeted applications.

In some embodiments, the optical system may comprise a plurality of lenses and mirrors and configured to focus and direct incoming hyperspectral images to optimize signal path efficiency and image clarity. For example, a converging lens may initially focus the dispersed light signals, while strategically positioned mirrors redirect the path to align with the sensor array as described in detail below. Adjustable tilts and angles ensure optimal focus across the full spectrum of received signals. The hyperspectral images from the plasma 261 may comprise both spatial and spectral information that can be used to analyze spatial distribution and uniformity of the plasmas. The optical system ensures that these complex signals are accurately transmitted to subsequent components, facilitating detailed examination and interpretation.

In some embodiments, the sensor of the HSI camera 280 may be configured to convert received hyperspectral images to digital data, which may include light intensity as a function of wavelength across different spatial pixels. The sensor may comprise a plurality of scientific complementary metal-oxide-semiconductor (CMOS) image sensors, charge-coupled device (CCD) sensors, or other advanced photosensors. These components are capable of measuring light intensity at each pixel from the process chamber 210. In certain embodiments, the sensor may comprise a CCD sensor with a capability of millisecond time resolution to capture dynamic plasma changes. In another embodiment, the sensor may comprise a CMOS image sensor with a high temporal resolution in microsecond.

In various embodiments, the memory may be a non-transitory memory configured to record and store the digital data and a program comprising instructions which are executed by one or more processors to perform the various functions described herein. For example, the memory may generally include both volatile memory and non-volatile memory, for example, random access memory (RAM), read only memory (ROM), or the like. The memory is capable of storing computer-readable, processor-executable program instructions as computer program code that may be executed by the processor(s) as a particular machine configured for carrying out the operations and functions described in the implementations herein.

In some embodiments, the hyperspectral images detected by the HSI camera 280 may comprise comprehensive spatial and spectral information, distinguishing them from traditional methods like spectrometers and white light color cameras (or multiple wavelength RGB cameras). Unlike these methods, which focus on limited spatial dimensions, for example, one dimension, or limited wavelength channels, for example, tens of wavelength channels, HSI camera 280 may capture a full spectrum for each pixel, offering a complete view of both spatial uniformity and spectral characteristics. In various embodiments, the HSI camera 280 may simultaneously acquire full spatial and spectral information across hundreds to thousands of wavelength channels, offering improved resolution.

The spatial information in hyperspectral images enables the detection of uniformity changes and provides insights into the chemical species present in the gas or plasma through identifying unique spectral signatures associated with these chemical species. For example, the HSI camera 280 may be configured to detect various chemical species including halides of silicon and the halogen species itself (e.g. chlorine, fluorine, and bromine). In some embodiments, the plasma processing may comprise etching of silicon oxide using a fluorine-containing chemistry, such as a fluorocarbon or hydrofluorocarbon gas. In such embodiments, it is useful to dynamically detect halides of silicon and the halogen species that are released by the decomposition of the fluorocarbon or hydrofluorocarbon gas in order to monitor the etching process for its process and stability. Other detectable byproducts may include carbon monoxide, and carbon dioxide, formed by reaction of oxygen from a film or gas mixture with carbon from the fluorocarbon or hydrofluorocarbon gas.

In various embodiments, the chamber control unit 255 may be configured to enable feedback control of the etching process, for example, based on a process monitoring using the HSI camera 280. The chamber control unit 255 may comprise a function generator including an appropriate digital and/or analog circuitry such as oscillators, pulse generators, modulators, combiners, and the like. The function generator is capable of generating one or more arbitrary waveforms that may be used for both power modulation of the RF power sources and hyperspectral data acquisition. In certain embodiments, some of the power modulation may be performed by the RF power sources themselves instead of the function generator. In such cases, the function generator may generate a pulse train synchronized with the power modulation by the RF power sources for hyperspectral data acquisition. In certain embodiments, although not illustrated, additional components (e.g., a broadband amplifier and a broadband impedance matching network) may be connected to the RF power sources.

In certain embodiments, power sources may comprise a DC power source. The RF and/or DC power sources (e.g., the RF power sources 240 and 244) may be configured to generate a continuous wave (CW) RF, pulsed RF, DC, pulsed DC, a high frequency rectangular (e.g., square wave) or triangular (e.g., sawtooth) pulse train, or a combination or superposition of more than one such waveform. In addition, power sources may be configured to generate a periodic function, for example, a sinusoid whose characteristics such as amplitude and frequency may be adjusted during a plasma process.

In some embodiments, a frequency for the RF source powers 240 and 244 may range from about 0.1 MHz to about 6 GHz. In certain embodiments, the RF power sources 240 and 244 may be used to provide a low frequency RF power and a high frequency RF power at the same time, respectively.

In certain embodiments, the etching process may be carried out using a pulsed plasma. The pulsed plasma in this disclosure refers to any type of plasma where a source power, a bias power, or both is pulsed at any frequency. In various embodiments, a pulsing at a frequency between 0.1 kHz and 100 kHz may be used to modulate the plasma source power or the bias power. In certain embodiments, a RF pulsing at a kHz range may be used to power the plasma. In various embodiments, any duty ratio (e.g., 0.1% to 99.9%) may be used for any plasma tool. In certain embodiments, a moderate duty ratio between 10% to 70% or 10% to 80% may be used for capacitively coupled plasma (CCP), and 3% to 90% for inductively coupled plasma (ICP). In one embodiment, a sinusoidal RF signal of 1 MHz may be modulated with an on-off frequency of 100 Hz. In another embodiment, a DC signal may be modulated with an on-off frequency of 100 Hz. In yet another embodiment, a square DC pulse signal of 1 MHz may be modulated with an on-off frequency of 100 Hz. In an alternate embodiment, cyclic modulation of RF or fast DC pulse waveform may be performed at a lower frequency (e.g., <100 Hz) using an algorithm.

FIG. 2B illustrates a schematic view of a processing system 22 with an optical emission spectroscopy (OES) detector coupled to an exhaust plasma chamber, in accordance with an embodiment. This configuration represents an alternative approach to endpoint detection for etching repeating stacks illustrated in FIGS. 1A-1D. In one or more embodiments, processing of the substrate 100 illustrated in FIGS. 1A-1D may be performed in the processing system 22. Components and features in FIG. 2B that shares reference numbers with those in FIG. 2A have corresponding structures and operations as previously described.

In various embodiments, an OES measurement assembly 25 may be coupled to the process chamber 210. The OES measurement assembly 25 may comprise an exhaust chamber 265 that is coupled to the exhaust line 220 via a tee conduit 225 disposed between the vacuum pumps 252 and an additional vacuum pump 254. Although the positioning of the exhaust chamber 265 may not be limited to any particular location, placing the exhaust chamber 265 to this particular portion of the exhaust line 220 downstream from the process chamber 210 (i.e., between the vacuum pump 252 and the additional vacuum pump 254) may be mechanically more feasible compared to other locations due to limited space. In various embodiments, an exhaust plasma may be generated from the exhaust gas in the exhaust chamber 265 and its optical signals may be measured by an OES detector 260 through a transparent viewport 230. The optical signals may be transmitted to the OES detector 260 through an optical fiber 232 that connects to the transparent viewport 230. Although not illustrated in FIG. 2B, the exhaust chamber 265 may further be coupled to any elements that may be useful for sustaining the exhaust plasma (e.g., throttle valve, additional gas inlet, and additional gas outlet).

In one or more embodiments, the exhaust chamber 265 may be equipped with a temperature controller (e.g., heating/cooling system). In one embodiment, the temperature in the exhaust line 220 and/or the exhaust chamber 265 may be kept relatively high to prevent residual by-product accumulation on the surfaces.

In various embodiments, the exhaust chamber 265 may improve the signal-to-noise ratio (SNR) of optical emission spectroscopy by amplifying the optical signal from byproduct species. During the etching process, reaction byproducts and etch gases may be continuously evacuated from the process chamber 210 to the exhaust chamber 265. Within the exhaust chamber 265, a RF power source 275 may be used as a power supply for generating the exhaust plasma, and a plasma coupler 285 may be disposed outside the walls of the exhaust chamber 265. Although not specifically illustrated, the RF power source 275 may comprise a power generator, an amplifier, a function generator, and a matching network. In addition, embodiments may include additional power sources to the exhaust chamber 265. For example, a reference or ground electrode may also be introduced and coupled to a reference potential node or DC power supply node.

Note that in FIG. 2B, only one of two exhaust lines 220 is shown coupled to the exhaust chamber 265, in some embodiments, these two exhaust lines 220 may merge into a single exhaust path before coupling to the exhaust chamber 265, allowing for monitoring of exhaust gases collected from both exhaust lines 220.

In various embodiments, the plasma coupler 285 may be a conductive helix coiled horizontally around the walls comprising a dielectric (e.g., a ceramic material). The plasma coupler 285 may alternatively be shaped like a planar coil. The plasma coupler 285 may be coupled to the RF power source 275. In various embodiments, the oscillation frequency of the RF power may be about 400 kHz to about 5 GHz and, in certain embodiment about 15 MHz to about 200 MHz. In one embodiment, the frequency of the RF power may be between 20 MHz to 40 MHz, for example 27 MHz. When a resonator helical coil is used for the plasma coupler 285, the frequency may be selected in consideration of the coil length such that the coil may sufficiently surround the walls of the exhaust chamber 265. The plasma coupler 285 may be configured to operate in a purely inductively or capacitively coupled mode to sustain the exhaust plasma with an RF power density of about 0.01 W/cm³ to about 30 W/cm³ within the exhaust chamber 265. In one embodiment, the RF power source may be operated in pulsing mode with a peak power up to about 1000 W/cm³.

In various embodiments, the OES detector 260 may comprise an optical system which may include a plurality of lenses and mirrors and configured to focus and direct incoming optical signals to optimize signal path efficiency. For example, a converging lens may initially focus the dispersed light signals, while strategically positioned mirrors redirect the path to align with sensors as described in detail below. Adjustable tilts and angles ensure optimal focus across the full spectrum of received signals.

In acquiring the optical emission data, the OES detector 260 may comprise, for example, a spectrometer that samples an optical emission spectrum of a plasma covering a range of wavelengths. The spectrum, in this example, may include light intensity as a function of wavelength or frequency. The OES detector 260 may comprise a charge-coupled device (CCD) sensor, a complementary metal oxide semiconductor (CMOS) image sensor, or other type of light detection device or photosensor may be utilized to measure the light intensity from the exhaust chamber 265. In certain embodiments, the sensor may comprise a CCD sensor with a capability of millisecond time resolution. In another embodiment, the sensor may comprise a CMOS image sensor with a capability of microsecond time resolution.

In some embodiments, the signal from the sensors of the OES detector 260 may be processed through an amplifier to increase signal strength while maintaining signal fidelity. In some embodiments, an analog-to-digital converter (ADC) may convert the amplified analog signals into discrete digital values. In one or more embodiments, a processor may interface with the ADC to receive and process the digital spectral data, which may include light intensity as a function of wavelength.

In various embodiments, the OES detector 260 may comprise a memory which may be a non-transitory memory configured to record and store the digital data and a program comprising instructions which are executed by one or more processors to perform the various functions described herein. For example, the memory may generally include both volatile memory and non-volatile memory, for example, random access memory (RAM), read only memory (ROM), or the like. The memory is capable of storing computer-readable, processor-executable program instructions as computer program code that may be executed by the processors as a particular machine configured for carrying out the operations and functions described in the implementations herein.

In various embodiments, a control unit 295 may be coupled to the OES detector 260, the RF power source 275 and the exhaust chamber 265. Although not specifically illustrated, the control unit 295 may comprise various electrical components required to analyze the data from the OES detector 260 as well as feedback control of the processing system 22 and the OES detector 260. Such components may include a transceiver, an amplifier, an analog-to-digital convertor (ADC), a filter, a memory, and a processor. In various embodiments, the OES detector 260 may be configured to perform a series of operations according to a command from the control unit 295: transmit the OES signals from the exhaust chamber 265 to the OES detector 260, OES data acquisition at the OES detector 260, receiving the OES data at a transceiver, filtering the OES data at a filter, and determining a characteristic of the plasma at the processor. The characteristic of the plasma may, for example, be plasma density, and/or concentrations of reactive ion species, etch byproduct, or other species of interest. The characteristic of the plasma may also include information on electron temperature. In certain embodiments, the OES detector 260 may be further configured to process the obtained raw OES data by, for example, averaging and/or smoothing prior to determining the characteristic of the plasma.

Note that the configurations of the processing systems 20 and 22 illustrated in FIGS. 2A and 2B are only for example. Various other configurations may be used for a processing system. In various embodiments, the processing systems may be a capacitively coupled plasma (CCP) system as illustrated in FIGS. 2A and 2B, or alternately an inductively coupled plasma (ICP) plasma system. In alternate embodiments, the processing systems may comprise a resonator such as a helical resonator. Further, microwave plasma (MW) or other suitable systems may also be used. In various embodiments, the RF power, chamber pressure, substrate temperature, gas flow rates and other plasma process parameters may be selected in accordance with the respective process recipe.

During the etching process illustrated in FIGS. 1A-1D, endpoint detection may be performed using one of two embodiments described in FIGS. 2A and 2B. In accordance with the embodiment shown in FIG. 2A, the HSI camera 280 may be coupled to the process chamber through a transparent viewport to monitor the etching process. The HSI camera 280 may acquire hyperspectral images of the plasma in the process chamber during the etching process, capturing both spatial and spectral information simultaneously.

In various embodiments, the HSI camera 280 may monitor specific wavelengths in the hyperspectral images corresponding to the first material layers 104 and second material layers 106. In some embodiments, the first material layers 104 may comprise oxide layers and the second material layers 106 may comprise nitride layers. The HSI camera 280 may identify oscillating intensity patterns in the specific wavelengths during alternative etching of the first and the second material layers 104 and 106. In some embodiments, the specific wavelengths may be around 440 nm corresponding to SiF emissions from etching of oxide layers and around 387 nm corresponding to CN emissions from etching of the nitride layers. These oscillating patterns may directly correspond to the alternating etching of the oxide and nitride layers in the repeating stacks. The HSI camera 280 may process the hyperspectral data to enhance SNR through spatial and frame averaging techniques, allowing for clear detection of these oscillation patterns in etched features with high aspect ratio and small open area. In some embodiments, the HSI camera 280 may enhance SNR of the hyperspectral images by: performing a frame average at a fixed time duration over each image pixel of the hyperspectral images; applying a filter algorithm to reduce noise of the frame averaged hyperspectral images; calculating SNR for each image pixel; ranking SNR values from high to low for different image pixels; selecting image pixels with high SNR values for spatial averaging; and calculating a final SNR based on the selected image pixels.

In accordance with the alternative embodiment shown in FIG. 2B, endpoint detection may be performed using the OES detector 260 coupled to an exhaust chamber. In this approach, exhaust gas containing etching byproducts may be removed from the process chamber through exhaust gas lines to the exhaust chamber. An RF power source may generate an exhaust plasma from the exhaust gas within the exhaust chamber. The OES detector 260 may be coupled to the exhaust chamber through a transparent viewport and an optical fiber, continuously acquiring OES data of the exhaust plasma during alternative etching of the first and the second material layer 104 and 106.

In various embodiments, the OES detector 260 may monitor specific wavelengths in the OES data corresponding to the oxide layers and nitride layers, focusing on the same characteristic wavelengths of about 440 nm for oxide etching and about 387 nm for nitride etching as described above. As the etching progresses through the alternating layers shown in FIG. 1C, the OES detector may identify oscillating intensity patterns in these specific wavelengths, with each oscillation cycle corresponding to the etching of one pair of oxide and nitride layers. In various embodiments, the endpoint of etching the repeating stack may be determined when the oscillating intensity pattern is ceased.

FIGS. 3A-3C illustrate comparative data showing endpoint detection capabilities of different monitoring systems (HSI and OES), in accordance with an embodiment. Both data (represented by curves 302, 304, and 306) are collected with the different monitoring systems coupled to the process chamber similar to the configuration in FIG. 2A.

FIGS. 3A and 3B shows intensity versus time data comparing the endpoint detection performances of a hyperspectral imaging (HSI) camera represented by the curve 302 and a conventional optical emission spectroscopy (OES) detector represented by the curve 304. The data was collected during an etching experiment using a small coupon to simulate a small open area ratio of 0.1%, with a 1 cm coupon on bare silicon. The HSI camera may be operated under conditions of 12-bit, 5 ms exposure time, and 20 frames average). FIG. 3A shows that the HSI camera may capture an intensity change at the endpoint 310. The HSI system utilizes spatial averaging across multiple pixels and frame averaging to enhance the signal-to-noise ratio, with approximately 1820 hotspot pixels contributing to the signal.

FIG. 3B shows the corresponding data from a conventional C5K OES detector (under operating conditions of 16-bit, 11 ms exposure time, and 9 frames average) for the same etching process in FIG. 3A. Despite using similar averaging techniques, the OES detector shows no discernible endpoint signal. The signal-to-noise ratio may be too low to detect the endpoint, demonstrating the limitations of conventional OES detector when coupled to process chamber to detect signals from features of small open area ratios.

FIG. 3C illustrates the challenges encountered when processing an ONO wafer with multiple alternating layers using a conventional OES detector (coupled to the process chamber). The OES data shows only weak oscillating intensity patterns 306, which are characteristic of etching repeating stacks of alternating materials. In this case, the OES detector can only detect oscillations from the top few layer pairs but fail to maintain high signal-to-noise ratio to track oscillations through the entire stack depth. The limits in OES detector when coupled to the process chamber may reduce the accuracy of endpoint detection during the etching of repeating stacks, particularly for high aspect ratio features with small open areas, as the weak oscillating patterns make it difficult to determine when the oscillations cease, an indicator of endpoint.

FIGS. 4A-4B illustrate oscillating intensity patterns that may be observed by the HSI camera (coupled to the process chamber) or OES detector (coupled to the exhaust chamber) during etching of repeating stacks (e.g., processing steps illustrated in FIGS. 1B and 1C) and their cessation at endpoint (e.g., processing step illustrated in FIG. 1D), in accordance with an embodiment.

FIG. 4A shows a representative oscillating intensity pattern comprising a series of intensity peaks (maxima) 402 and valleys (minima) 404 plotted against time during the etching of repeating stacks of alternating material layers. In an embodiment shown in FIG. 4A, the oscillating intensity pattern may exhibit rounded or rectangular waveforms with distinct rises and falls as the etching progresses through the alternating layers (104 and 106).

FIG. 4B represents another exemplary shape of the oscillating intensity pattern that may be observed during the etching process. In contrast to the more rounded or rectangular pattern shown in FIG. 4A, FIG. 4B displays a more triangular waveform in the oscillating intensity pattern, with sharper transitions between peaks 402 and valleys 404. In various embodiments, different waveform shapes may result from variations in etching conditions, chamber configurations, or detection methods.

Despite the different shape, each cycle of peak and valley may correspond to the etching of one pair of first and second material layers 104 and 106. In an embodiment when monitoring a wavelength of about 440 nm corresponding to SiF emissions from the etching of oxide layers, the peaks 402 may indicate high concentration of SiF byproducts during oxide etching periods, while the valleys 404 may correspond to periods when nitride layers are being etched when minimal SiF byproducts are generated.

FIGS. 4A and 4B illustrate a cessation of the oscillating intensity pattern with a transition to a relatively flat intensity pattern after point 410, indicating that the endpoint may be reached. The cessation of oscillations may occur when the etching process has progressed through all the alternating material layers in the repeating stacks (e.g., the substrate 100 illustrated in FIG. 1D).

For illustration purposes, FIGS. 4A and 4B only show approximately 5 peaks and valleys in the oscillating intensity pattern. In practical applications involving ONO stacks or similar structures, the number of oscillation cycles may range from 100 to 200 depending on the number of pairs of alternating layers in the repeating stacks, with each pair contributing to one cycle of peak and valley in the intensity pattern. The ability to detect these oscillations throughout the entire etching process and identify when they cease enables accurate endpoint detection for these complex structures.

In one or more embodiments, the cessation of oscillating intensity patterns observed in the endpoint detection data shown in FIGS. 4A-4B may correspond to the endpoint condition illustrated in FIG. 1D. When the oscillating intensity pattern at the monitored wavelengths (e.g., approximately 440 nm for SiF emissions from oxide etching and 387 nm for CN emissions from nitride etching) cease and transition to a relatively flat or gradually decreasing intensity pattern, it indicates that the etching has progressed through all the alternating material layers and reached the substrate layer 102.

In high aspect ratio features with small open areas, conventional endpoint detection methods (e.g., monitoring the optical signals in the process chamber through the OES detector) may fail to accurately determine the endpoint, leading to either under-etching (where some repeating stack layers remain) or over-etching (where the substrate layer 102 is unnecessarily etched). The hyperspectral imaging approach or the OES with exhaust plasma chamber approach described in FIGS. 2A and 2B may provide the necessary signal-to-noise ratio to clearly detect when the oscillations cease, enabling precise endpoint detection even in etching features with high aspect ratio and small open area.

In various embodiments, detecting oscillating intensity patterns may provide advantages over conventional endpoint detection methods that rely solely on a single intensity change. In conventional approaches, endpoint detection may depend on observing a distinct drop or rise in emission intensity when transitioning from one material to another, which becomes unreliable for complex structures with multiple alternating layers. By monitoring oscillating intensity patterns that correspond to the sequential etching of alternating material layers, the precise progression through each layer pair in the repeating stack may be tracked to provide continuous feedback throughout the entire etching process rather than just at the final transition. This method may be particularly valuable for ONO stacks and similar structures where multiple material transitions occur before reaching the final endpoint. Additionally, the oscillation-based approach may help confirm that etching is proceeding as expected through each layer, allowing for early detection of process anomalies. When these oscillations eventually cease, it provides a clear, unambiguous indication that all alternating layers have been etched, even in challenging scenarios with high aspect ratios and small open areas where conventional single-transition detection often fails due to weak signal-to-noise ratio.

FIG. 5 illustrates a process flow diagram for an HSI-based endpoint detection method for etching a substrate with repeating stacks, in accordance with an embodiment.

At block 502, a substrate may be loaded in a process chamber, the substrate comprising repeating stacks of alternating first material layers and second material layers. This substrate may be similar to the substrate 100 as described with reference to FIG. 1A, which may include the repeating stacks of alternating oxide layers 104 and nitride layers 106 disposed over the substrate layer 102.

At block 504, the repeating stacks may be etched by exposing the substrate to an etching process, such as a continuous or cyclic plasma process, to etch the repeating stacks of the alternating first material layers and second material layers. This etching process may be similar to the process described with reference to FIGS. 1B and 1C, where the plasma 10 may be generated from an etch gas comprising fluorocarbon components and other gases. The etching may form etched features 114 with high aspect ratios over 10:1 and open area ratios of less than 10% of the total surface area.

At block 506, while etching the repeating stacks, hyperspectral images of the plasma may be acquired and specific wavelengths corresponding to each material layer may be monitored. In various embodiments, hyperspectral images of the plasma may be collected by the HSI camera 280 coupled to the process chamber through the transparent viewport 290 as described with reference to FIG. 2A. In some embodiments, the specific wavelengths may include approximately 440 nm for monitoring SiF emissions during oxide layer etching and approximately 387 nm for monitoring CN emissions during nitride layer etching.

At block 508, spatial and frame averaging may be applied to the hyperspectral data to improve signal-to-noise ratio. As described in reference to FIG. 2A, the HSI camera 280 may perform various signal enhancement techniques including spatial averaging across multiple pixels and frame averaging across multiple frames to significantly improve the signal-to-noise ratio compared to conventional OES methods.

At block 510, the hyperspectral data may be analyzed to identify oscillating intensity patterns corresponding to the alternating etching of the first and second material layers. These oscillating patterns may be similar to those illustrated in FIGS. 4A and 4B, where the intensity peaks 402 and valleys 404 may correspond to the sequential etching of alternating material layers in the repeating stacks.

At block 512, the etching process may be stopped when the oscillating intensity pattern at the monitored wavelengths ceases, indicating the endpoint has been reached. This endpoint condition may correspond to the state shown in FIG. 1D, where the etching has progressed through all the repeating stacks to expose the top surface of the substrate layer 102.

FIG. 6 illustrates a process flow diagram for an OES-based endpoint detection method using an exhaust plasma chamber, in accordance with an embodiment.

At block 602, a substrate may be provided in a process chamber, the substrate comprising repeating stacks of a first material layer and a second material layer. This substrate may be similar to the substrate 100 as described with reference to FIG. 1A, which may include the repeating stacks of alternating oxide layers 104 and nitride layers 106 disposed over the substrate layer 102.

At block 604, the repeating stacks may be etched, and exhaust gas in the process chamber may be removed to an exhaust chamber coupled to the process chamber. This etching process may be similar to the process described with reference to FIGS. 1B and 1C, where etched features 114 with high aspect ratios over 10:1 and open area ratios of less than 10% may be formed. The exhaust gas removal may follow the configuration shown in FIG. 2B, where exhaust lines 220 may direct the exhaust gas containing etching byproducts from the process chamber 210 to the exhaust chamber 265.

At block 606, during the etching, an exhaust plasma may be generated from the exhaust gas in the exhaust chamber. As described with reference to FIG. 2B, the RF power source 275 may generate the exhaust plasma through the plasma coupler 285, which may be a conductive helix or planar coil operating at frequencies from 400 kHz to 5 GHz.

At block 608, optical emission spectroscopy (OES) data of the exhaust plasma may be continuously acquired through an OES detector coupled to the exhaust chamber, and specific wavelengths corresponding to each material layer may be monitored. The OES data may be obtained by the OES detector 260 coupled to the exhaust chamber 265 through the transparent viewport 230 and optical fiber 232 as described with reference to FIG. 2B. In some embodiments, the specific wavelengths may include approximately 440 nm for monitoring SiF emissions during oxide layer etching and approximately 387 nm for monitoring CN emissions during nitride layer etching.

At block 610, the OES data may be analyzed to identify oscillating intensity patterns corresponding to the alternating etching of the first and second material layers. These oscillating patterns may be similar to those illustrated in FIGS. 4A and 4B, where the intensity peaks 402 and valleys 404 may correspond to the sequential etching of alternating material layers in the repeating stacks. In embodiments comprising ONO stacks with approximately 133 pairs of alternating layers, the oscillation pattern may include 100 to 200 cycles, with each cycle representing the etching of one pair of material layers.

At block 612, the etch may be stopped when the oscillating intensity pattern at the monitored wavelengths ceases, indicating the endpoint has been reached. This endpoint condition may correspond to the state shown in FIG. 1D, where the etching has progressed through all the repeating stacks to expose the top surface of the substrate layer 102.

While not explicitly shown in the flowcharts illustrated in FIGS. 5 and 6, additional steps may be performed as described in the previous figures. For example, the process may include flowing an etch gas into the process chamber and generating a plasma from the etch gas as described with reference to FIGS. 1B and 2A. For example, the exhaust chamber may be equipped with a temperature controller to prevent residual byproduct accumulation on the surfaces as mentioned in the description of FIG. 2B. Additionally, the method may include calculating a ratio of intensities at two different wavelengths to enhance signal-to-noise ratio as discussed in the endpoint detection techniques. These steps may be implemented as needed based on specific application requirements and desired etching outcomes.

While the inventive aspects are described primarily in the context of endpoint detection for etching ONO stacks with alternating oxide and nitride layers, it should also be appreciated that these inventive aspects may also apply to various other multilayer structures requiring precise endpoint detection during etching processes. In particular, aspects of this disclosure may similarly apply to metal-insulator-metal (MIM) stacks in capacitor structures, alternating metal/dielectric layers in optical filters, multilayer magnetic structures in MRAM devices, phase-change material stacks in PCM memory, alternating silicon/germanium layers in superlattice structures, alternating silicon/silicon-germanium layers in superlattice structures, III-V semiconductor heterostructures, thin-film transistor (TFT) layer stacks, OLED display layer structures, and photonic crystal fabrication where precise control of etching depth through multiple alternating layers is important for device performance and functionality.

Example embodiments of the invention are described below. Other embodiments can also be understood from the entirety of the specification as well as the claims filed herein.

Example 1. A method for processing a substrate, the method including: loading a substrate in a process chamber, the substrate including repeating stacks of alternating first material layers and second material layers; etching the repeating stacks by exposing the substrate to a plasma; determining an endpoint of the etching based on hyperspectral images of the plasma acquired during the etching; and stopping the etching after determining the endpoint.

Example 2. The method of example 1, further including enhancing signal-to-noise ratio (SNR) of the hyperspectral images by: performing a frame average at a fixed time duration over each image pixel of the hyperspectral images; applying a filter algorithm to reduce noise of the frame averaged hyperspectral images; calculating SNR for each image pixel; ranking SNR values from high to low for different image pixels; selecting image pixels with high SNR values for spatial averaging; and calculating a final SNR based on the selected image pixels.

Example 3. The method of one of examples 1 or 2, where the repeating stacks include 100 to 200 pairs of the first material layers and the second material layers.

Example 4. The method of one of examples 1 to 3, where each material layer of the repeating stacks has a thickness of 10 to 30 nm.

Example 5. The method of one of examples 1 to 4, where the plasma is generated from an etch gas including a fluorocarbon gas.

Example 6. The method of one of examples 1 to 5, where the first material layers include oxide layers and the second material layers include nitride layers.

Example 7. The method of one of examples 1 to 6, where the hyperspectral images of the plasma acquired during the etching include a wavelength of about 440 nm for the oxide layers and a wavelength of about 387 nm for the nitride layers.

Example 8. The method of one of examples 1 to 7, where determining the endpoint includes: monitoring specific wavelengths in the hyperspectral images corresponding to the first material layers and the second material layers; identifying oscillating intensity patterns in the specific wavelengths, the oscillating intensity patterns corresponding to alternating etching of the first material layers and the second material layers; and determining the endpoint of the etching when the oscillating intensity patterns cease.

Example 9. The method of one of examples 1 to 8, where the oscillating intensity patterns include a series of intensity maxima and minima with each cycle of the series corresponding to the etching of one pair of the first material layer and the second material layer.

Example 10. A method for endpoint detection during etching of multilayer structures, the method including: providing a substrate with repeating stacks of alternating first material layers and second material layers in a process chamber; initiating an etching process to etch the repeating stacks; coupling a hyperspectral imaging system to the process chamber to monitor the etching process; acquiring hyperspectral data from the etching process; processing the hyperspectral data to enhance signal-to-noise ratio; analyzing the hyperspectral data to identify oscillating intensity patterns at wavelengths associated with etching byproducts of the first material layers and the second material layers; monitoring changes in the oscillating intensity patterns during the etching process; and determining that an endpoint of the etching process is reached when the oscillating intensity patterns cease.

Example 11. The method of example 10, where the repeating stacks have a total thickness of 4 to 8 μm.

Example 12. The method of one of examples 10 or 11, where the etching process forms an etched feature in the repeating stacks with an aspect ratio over 10:1.

Example 13. The method of one of examples 10 to 12, where the etched feature has an open area ratio of less than 10% of a total surface area of the substrate.

Example 14. The method of one of examples 10 to 13, where the first material layers include oxide layers and the second material layers include nitride layers.

Example 15. The method of one of examples 10 to 14, where the wavelengths associated with the etching byproducts include a wavelength of about 440 nm for the oxide layers and a wavelength of about 387 nm for the nitride layers.

Example 16. The method of one of examples 10 to 15, further including stopping the etching process when an endpoint is reached.

Example 17. A method for processing a substrate, the method including: providing a substrate in a process chamber, the substrate including repeating stacks of alternating first material layers and second material layers; etching the repeating stacks in the process chamber; removing exhaust gas from the process chamber to an exhaust chamber coupled to the process chamber; generating an exhaust plasma from the exhaust gas in the exhaust chamber; coupling an optical emission spectroscopy (OES) detector to the exhaust chamber; continuously acquiring OES data of the exhaust plasma through the OES detector; monitoring specific wavelengths in the OES data corresponding to the first material layers and the second material layers; identifying oscillating intensity patterns in the specific wavelengths as the alternating first material layers and second material layers are etched; and determining an endpoint of the etching when the oscillating intensity patterns cease.

Example 18. The method of example 17, where coupling the OES detector to the exhaust chamber includes connecting a fiber optic cable between the OES detector and a viewport of the exhaust chamber.

Example 19. The method of one of examples 17 or 18, further including calculating a ratio of intensities at two different wavelengths to enhance signal-to-noise ratio.

Example 20. The method of one of examples 17 to 19, where the oscillating intensity patterns include a series of intensity peaks and valleys with each intensity peak of the series corresponding to the etching of the first material layer or the second material layer.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-6 may be combined in further embodiments. It is therefore intended that the appended claims encompass any such modifications or embodiments.

What is claimed is:

1. A method for processing a substrate, the method comprising:
loading a substrate in a process chamber, the substrate comprising repeating stacks of alternating first material layers and second material layers;
etching the repeating stacks by exposing the substrate to a plasma;
determining an endpoint of the etching based on hyperspectral images of the plasma acquired during the etching; and
stopping the etching after determining the endpoint.

2. The method of claim 1, further comprising enhancing signal-to-noise ratio (SNR) of the hyperspectral images by:
performing a frame average at a fixed time duration over each image pixel of the hyperspectral images;
applying a filter algorithm to reduce noise of the frame averaged hyperspectral images;
calculating SNR for each image pixel;
ranking SNR values from high to low for different image pixels;
selecting image pixels with high SNR values for spatial averaging; and
calculating a final SNR based on the selected image pixels.

3. The method of claim 1, wherein the repeating stacks comprise 100 to 200 pairs of the first material layers and the second material layers.

4. The method of claim 1, wherein each material layer of the repeating stacks has a thickness of 10 to 30 nm.

5. The method of claim 1, wherein the plasma is generated from an etch gas comprising a fluorocarbon gas.

6. The method of claim 1, wherein the first material layers comprise oxide layers and the second material layers comprise nitride layers.

7. The method of claim 6, wherein the hyperspectral images of the plasma acquired during the etching comprise a wavelength of about 440 nm for the oxide layers and a wavelength of about 387 nm for the nitride layers.

8. The method of claim 1, wherein determining the endpoint comprises:
monitoring specific wavelengths in the hyperspectral images corresponding to the first material layers and the second material layers;
identifying oscillating intensity patterns in the specific wavelengths, the oscillating intensity patterns corresponding to alternating etching of the first material layers and the second material layers; and
determining the endpoint of the etching when the oscillating intensity patterns cease.

9. The method of claim 8, wherein the oscillating intensity patterns comprise a series of intensity maxima and minima with each cycle of the series corresponding to the etching of one pair of the first material layer and the second material layer.

10. A method for endpoint detection during etching of multilayer structures, the method comprising:
providing a substrate with repeating stacks of alternating first material layers and second material layers in a process chamber;
initiating an etching process to etch the repeating stacks;
coupling a hyperspectral imaging system to the process chamber to monitor the etching process;
acquiring hyperspectral data from the etching process;
processing the hyperspectral data to enhance signal-to-noise ratio;
analyzing the hyperspectral data to identify oscillating intensity patterns at wavelengths associated with etching byproducts of the first material layers and the second material layers;
monitoring changes in the oscillating intensity patterns during the etching process; and
determining that an endpoint of the etching process is reached when the oscillating intensity patterns cease.

11. The method of claim 10, wherein the repeating stacks have a total thickness of 4 to 8 μm.

12. The method of claim 10, wherein the etching process forms an etched feature in the repeating stacks with an aspect ratio over 10:1.

13. The method of claim 12, wherein the etched feature has an open area ratio of less than 10% of a total surface area of the substrate.

14. The method of claim 10, wherein the first material layers comprise oxide layers and the second material layers comprise nitride layers.

15. The method of claim 14, wherein the wavelengths associated with the etching byproducts comprise a wavelength of about 440 nm for the oxide layers and a wavelength of about 387 nm for the nitride layers.

16. The method of claim 10, further comprising stopping the etching process when an endpoint is reached.

17. A method for processing a substrate, the method comprising:
providing a substrate in a process chamber, the substrate comprising repeating stacks of alternating first material layers and second material layers;
etching the repeating stacks in the process chamber;
removing exhaust gas from the process chamber to an exhaust chamber coupled to the process chamber;
generating an exhaust plasma from the exhaust gas in the exhaust chamber;
coupling an optical emission spectroscopy (OES) detector to the exhaust chamber;
continuously acquiring OES data of the exhaust plasma through the OES detector;
monitoring specific wavelengths in the OES data corresponding to the first material layers and the second material layers;
identifying oscillating intensity patterns in the specific wavelengths as the alternating first material layers and second material layers are etched; and
determining an endpoint of the etching when the oscillating intensity patterns cease.

18. The method of claim 17, wherein coupling the OES detector to the exhaust chamber comprises connecting a fiber optic cable between the OES detector and a viewport of the exhaust chamber.

19. The method of claim 17, further comprising calculating a ratio of intensities at two different wavelengths to enhance signal-to-noise ratio.

20. The method of claim 17, wherein the oscillating intensity patterns comprise a series of intensity peaks and valleys with each intensity peak of the series corresponding to the etching of the first material layer or the second material layer.
